(19) United States
(12) Patent Application Publication
(10) Pub. No.: US 2010/0259246 A1
(43) Pub. Date: Oct. 14, 2010

(54) SPLIT SHAPE CLOSED LOOP CURRENT TRANSDUCER

(76) Inventor: Jang-Soo Kim, Daegu (KR)

Correspondence Address: REINHART BOERNER VAN DEUREN P.C., 2215 PERRYGREEN WAY, ROCKFORD, IL, 61107, US

(21) Appl. No.: 12/682,372

(22) PCT Filed: Dec. 3, 2007
(86) PCT No.: PCT/KR2007/006196

§ 371 Date: Jun. 2, 2010

(30) Foreign Application Priority Data
Oct. 10, 2007 (KR) 10-2007-0101911

(51) Int. Cl. G01R 19/18

(52) U.S. Cl. 324/120

(57) ABSTRACT

A current transducer having an open/closed structure of a penetration piece through which a measurement target line passes, includes: one pair of Hall devices, formed on both end gaps of an upper side portion, for sensing a current amount of the line to be measured; a feedback coil, arranged on an upper portion of the Hall devices, for canceling out a magnetic flux density of a magnet by inducing a current of a reverse direction to a current conducted in the measurement target line; a closed loop current sensing circuit for measuring a current flowing into the feedback coil; and a signal conversion circuit section for converting a current form of the measurement target line measured from the closed loop current sensing circuit into a direct current conversion signal relative to an effective value required from equipment connected to the current transducer, and outputting the direct current conversion signal.

### TECHNICAL FIELD

The present invention relates to a current transducer, and more particularly, to a closed loop current transducer having an open/closed structure of a penetration piece that measures a current amount of a measurement target line in real time, converts a measured current into a direct current (DC) signal proportional to an effective value, and transfers the DC signal.

### BACKGROUND ART

The measurement of a current amount is applied at the time of measuring a consumed current amount at home or at the time of monitoring a power supply mounted in a switchboard system of a factory.

Moreover, the current amount may be measured in real time in power equipments of power conversion equipment, a power supply, an uninterruptible power supply system, an inverter, and the like, and the measured current amount may be used as information for preventing the equipment from being damaged due to an abnormal current or achieving high efficiency. This is widely used in the fields of alternative energy power generation systems usually using a battery and a power converter, electric railway vehicles, electric automobiles, ships, and airplanes.

A conventional current measurement technology is classified as a direct measurement method using a resistor and an indirect measurement method using a current transformer (CT) based on an electronic induction method and a current sensor using a Hall device.

The resistor used in the direct measurement method is based on a non-isolation method incapable of separating power to be measured and signal power as a method for cutting a line to be measured and directly connecting both ends of the measurement line, but has a problem in that an error is added due to resistor heating occurring at high power. The CT based on the electronic induction method serving as the indirect measurement method has a problem in that a measurement error is very large, or the measurement itself is impossible, in a non-sinusoidal wave except a sinusoidal waveform, a phase control wave of a power semiconductor, a DC/ripple current waveform.

For this reason, the current sensor based on the electronic current measurement method using the Hall device is recently being widely used which can measure any DC/alternating current (AC) in the indirect measurement method.

The method using the Hall device serving as the electronic current measurement method is classified into a method using an open loop current sensor for measuring a magnetic force of a magnet, amplifying an output voltage of the Hall device serving as a magnetoelectric conversion device, and outputting the amplified voltage and a method using a closed loop current sensor having a feedback coil. The technology of the current measurement method using the open loop current sensor and the CT resistor is well known.

Since a signal measured by current measurement products has the same form as that of power to be measured, there is inconvenience in that a dedicated signal converter should be additionally installed to convert the measured signal into a designated signal required for equipment when the equipment such as a computer, a PLC, recording equipment, display equipment, or the like using a current measurement signal is usually connected and used.

Moreover, current measurement products are inconvenient in that a line to be measured should be disassembled upon installation and disassembly since a measurement penetration piece is not separated or a direct connection to the line is required.

Accordingly, a user should have the electrical knowledge to use the products in different current waveforms of a non-sinusoidal wave, a phase controlled waveform, a DC, an AC, and the like. Otherwise, there is a problem in that a high error occurs and the measurement is impossible. Since a product of the dedicated signal converter is usually forcibly set to an approximate effective value using a mean value circuit, a measurement error problem occurs when a frequency or phase is different. To address this problem, the current measurement products usually use the CT for the current measurement of a commercial power supply in a switchboard system, and the current sensor using the resistor (shunt) or Hall device for the current measurement in a battery, power conversion equipment, an electric vehicle, and the like in which a non-sinusoidal waveform and a DC waveform are present. However, this structure also has a problem in that direct mounting on the line is required by separating the line or a penetration piece is not open/closed. There is a problem in that the line should be disassembled when a conventional technical product is mounted on an existing installed line, a current measurement product should be differently configured in a commercial power supply, a power phase control power supply, and a DC power supply, and a dedicated signal converter should be additionally attached to convert the measured signal into a designated signal required for equipment when the equipment such as a computer, a PLC, recording equipment, display equipment, or the like using a current measurement signal is usually connected and used.

### DISCLOSURE

### Technical Problem

The present invention has been made to solve the foregoing problems with the prior art, and therefore the present invention provides a closed loop current transducer having an open/closed structure of a penetration piece with high accuracy that can enable measurement in all of a commercial power supply, a power phase control power supply and a power supply of a DC/ripple current waveform and that can neglect a gap deviation in a separate structure.

Moreover, the present invention also provides a closed loop current transducer having a function of signal conversion into a form required for a computer, a PLC, recording equipment, display equipment, and the like in addition to current measurement, that is, a DC conversion function relative to an effective value irrespective of a DC/AC waveform.

### Technical Solution

According to an aspect of the present invention, there is provided a current transducer having an open/closed structure of a penetration piece through which a measurement target line passes. The current transducer includes one pair of Hall devices, formed on both end gaps of an upper side portion, for sensing a current amount of the line to be measured; a feedback coil, arranged on an upper portion of the Hall devices, for canceling out a magnetic flux density of a magnet by inducing a current of a reverse direction to a current conducted in the measurement target line; a closed loop current sensing circuit for measuring a current flowing into the feedback coil; and a signal conversion circuit section for converting a current form of the measurement target line measured from the closed loop current sensing circuit into a direct current conversion signal relative to an effective value required from equipment connected to the current transducer, and outputting the direct current conversion signal.

Preferably, the signal conversion circuit section includes an effective function calculation circuit for cross switching a time-divisionally differentiated waveform of a signal measured through the closed loop current measurement circuit, calculating a direct current signal relative to an effective value through a multi-integral method in a DS integral circuit, and outputting the direct current signal; and a direct current signal amplification circuit for amplifying and outputting the direct current signal output through the effective function calculation circuit.

Moreover, an input/output pattern of the Hall devices is formed to pass through a winding center of the feedback coil, and the Hall devices are formed on left and right gaps in a magnetic flux direction.

Moreover, a correction variable resistor is further formed to uniformly adjust left and right sensitivities of the Hall devices.

Moreover, a length ratio of an upper side portion and a lower side portion of the penetration piece is formed at 8:2 or 9:1.

Moreover, when an upper side portion and a lower side portion are separated with reference to a hinge, the current transducer is rotatable. More preferably, when the penetration piece of the current transducer configures a closed loop, a fixture for coupling and fixing the upper side portion and the lower side portion is further formed.

Moreover, an attachment hole for accommodating a nut connected to an attachment screw can be further formed to attach the current transducer to a frame or bracket.

### Advantageous Effects

As set forth above, the present invention provides a closed loop current transducer having an open/closed structure of a penetration piece with high accuracy that can enable measurement in all of a commercial power supply, a power phase control power supply and a power supply of a DC/ripple current waveform and that can neglect a gap deviation in a separate structure.

Moreover, the present invention provides a closed loop current transducer having a function of signal conversion into a form required for a computer, a PLC, recording equipment, display equipment, and the like in addition to current measurement, that is, a DC conversion function relative to an effective value irrespective of a DC/AC waveform.

### DESCRIPTION OF DRAWINGS

FIG. 1 is a view showing an external appearance of a closed loop current transducer having an open/closed structure of a penetration piece according to a preferred embodiment of the present invention.

FIG. 2 is an assembly exploded view of the closed loop current transducer having the open/closed structure of the penetration piece according to a preferred embodiment of the present invention.

FIG. 3 is an internal exploded view of the closed loop current transducer having the open/closed structure of the penetration piece according to a preferred embodiment of the present invention.

FIG. 4 shows an example of implementing the closed loop current transducer having the open/closed structure of the penetration piece according to a preferred embodiment of the present invention.

FIG. 5 is a circuit configuration view of the closed loop current transducer having the open/closed structure of the penetration piece according to a preferred embodiment of the present invention.

### BEST MODE

For better understanding of the present invention and the objects capable of being achieved by implementing the present invention, the accompanying drawings illustrating preferred embodiments of the present invention and contents described with reference to the accompanying drawings should be referenced.

Hereinafter, the present invention will be described in detail by describing the preferred embodiments of the present invention with reference to the accompanying drawings. The same reference numerals described in the drawings denote the same members.

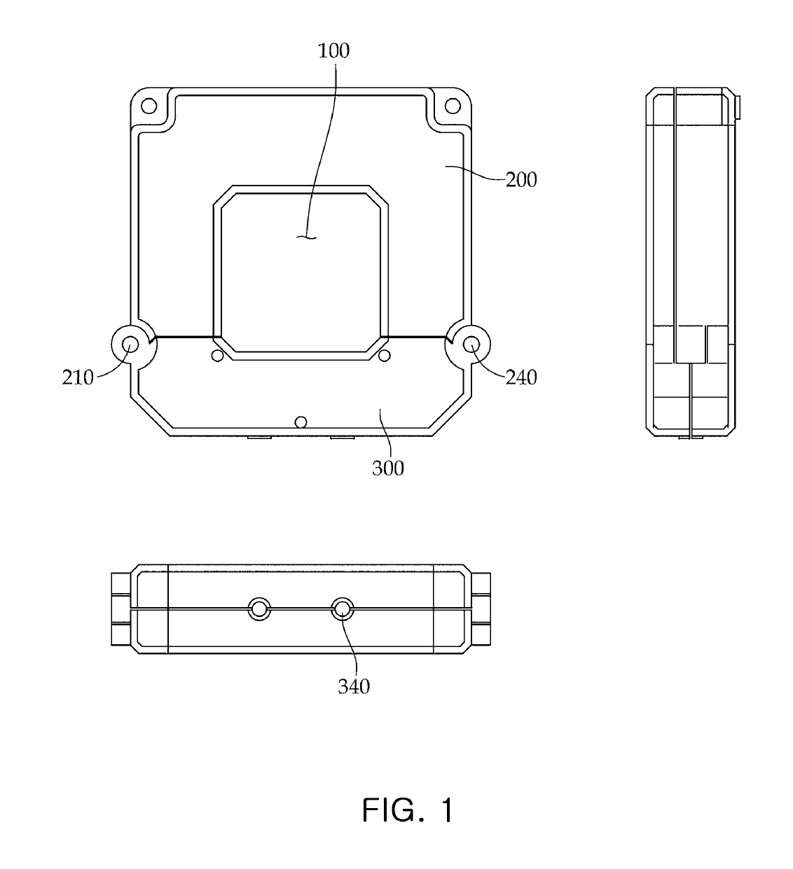

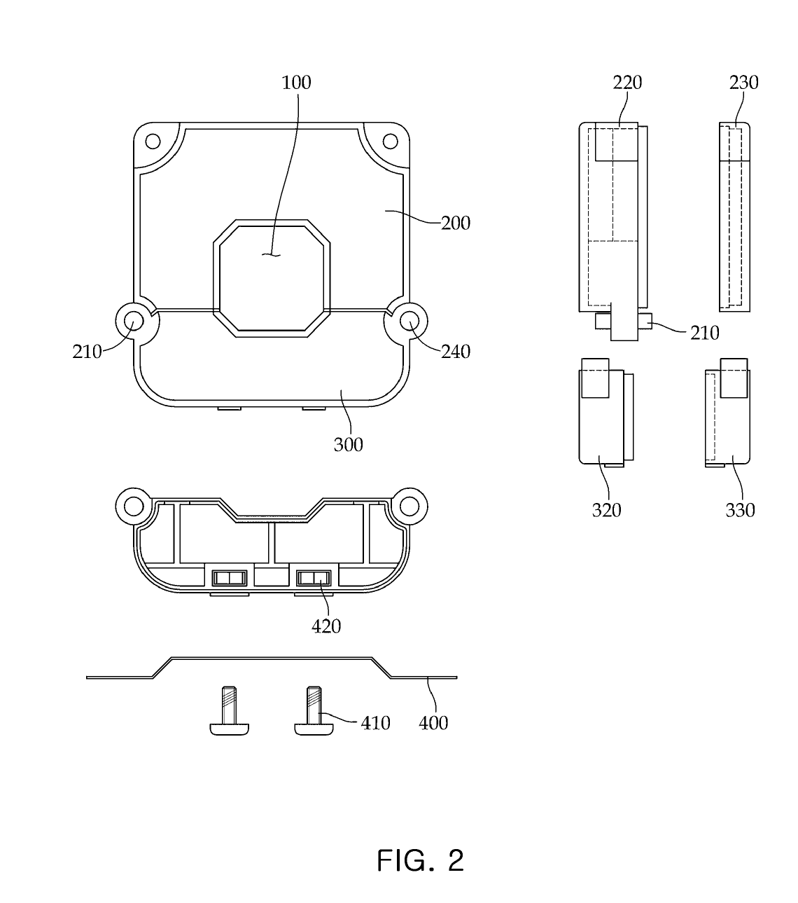

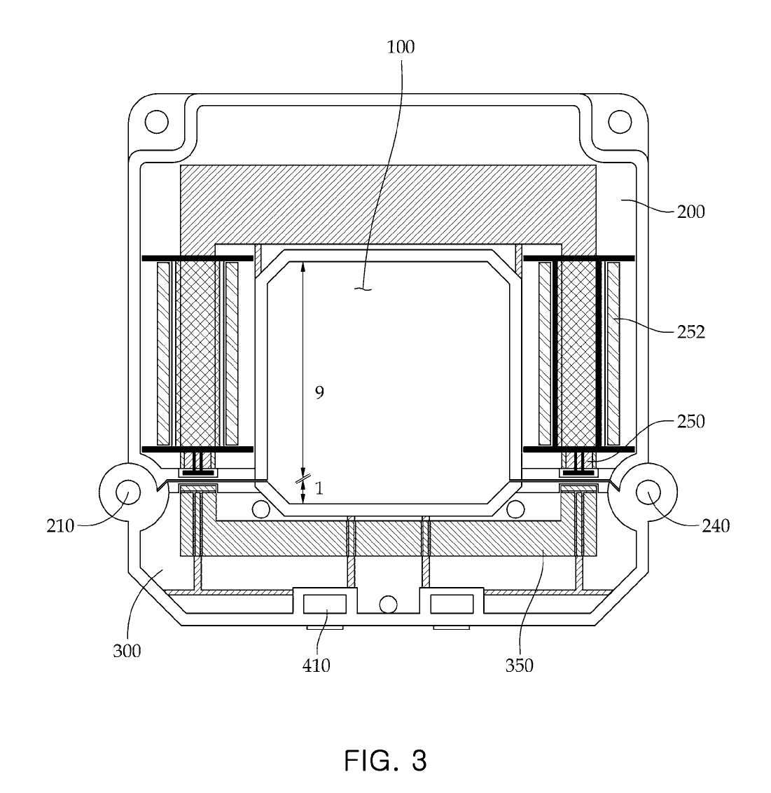

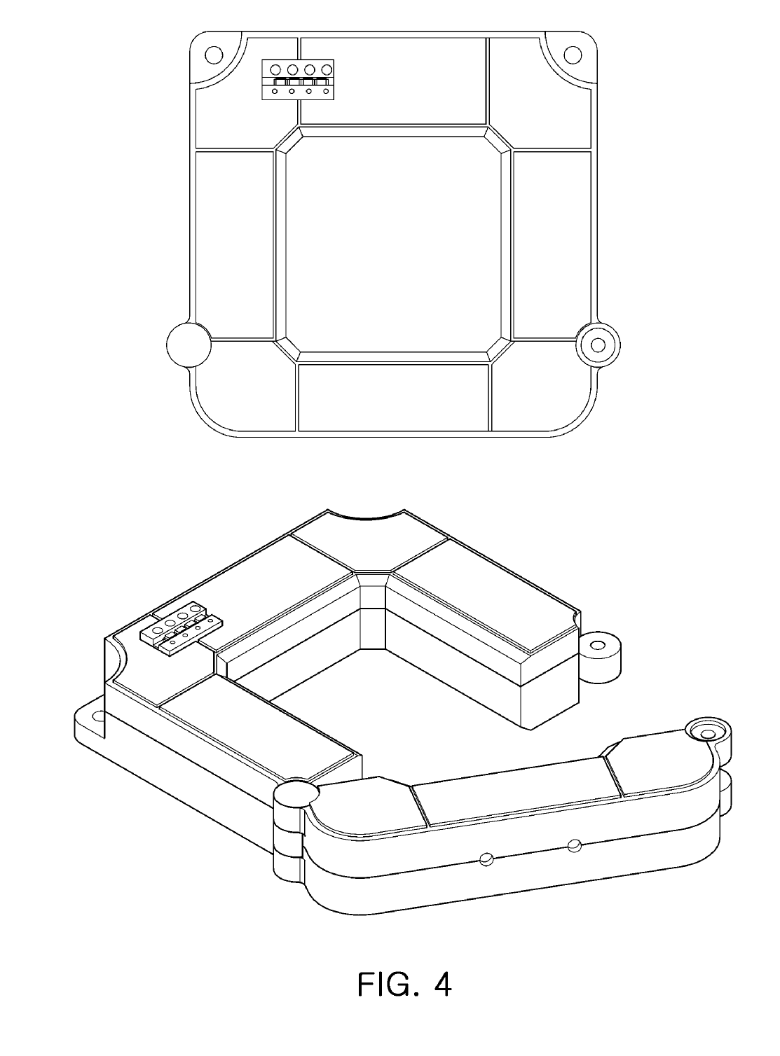

FIG. 1 is a view showing an external appearance of a closed loop current transducer having an open/closed structure of a penetration piece according to a preferred embodiment of the present invention, FIG. 2 is an assembly exploded view of the closed loop current transducer having the open/closed structure of the penetration piece according to a preferred embodiment of the present invention, FIG. 3 is an internal exploded view of the closed loop current transducer having the open/closed structure of the penetration piece according to a preferred embodiment of the present invention, and FIG. 4 shows an example of implementing the closed loop current transducer having the open/closed structure of the penetration piece according to a preferred embodiment of the present invention.

Referring to FIGS. 1 to 4, the closed loop current transducer having the open/closed structure of the penetration piece of the present invention is rotatable when an upper side portion 200 and a lower side portion 300 are separated with respect to a hinge 210 to implement the open/closed structure of a separate type penetration piece 100 in the external appearance having a structure in which the penetration piece is open/closed. The upper side portion 200 and the lower side portion 300 have a structure for protecting internal components by coupling bodies 220, 320 and covers 230, 330.

More specifically, in the upper side portion 200, the hinge 210 is arranged to form a rotation center such that the upper side portion 200 and the lower side portion 300 can be supported and open/closed. A fixture 240 is formed to couple and fix the upper side portion 200 and the lower side portion 300 such that the penetration piece 100 configures the closed loop. To attach the current transducer of the present invention to a frame or bracket 400, an attachment hole 340 for accommodating and supporting an attachment screw 410 and a nut 420 connected thereto can be additionally formed.

An internal configuration of the current transducer of the present invention will be described in detail. Hall devices 250 serving as magnets for sensing a current amount of a measurement target line 110 are formed at both ends of the upper side portion 200, and a voltage-current amplification circuit 251 is formed to amplify a current sensed from the Hall devices 250 and to configure a feedback loop such that a current can flow in a reverse direction to a measurement target current. More specifically, a feedback coil 252 is formed in the current transducer of the present invention. As the current is induced to flow in the reverse direction to the measurement target current from the feedback coil 252, a magnetic flux density of the magnet is set to “0,” such that the magnetic flux density of a measurement point is maintained to “0” irrespective of a large or small current amount flowing into the measurement target line 110. At this time, the current flowing into the feedback coil 252 is used as a current measurement output signal. Advantageously, this operation method does not depend upon the characteristics of a magnet 350.

Moreover, to minimize an eccentric effect in a closed loop current sensing circuit in the penetration piece 100 upon current measurement, a length ratio of the upper side portion 200 and the lower side portion 300 of the penetration piece 100 is formed at 8:2 or 9:1. A gap of the magnet 350 is formed, the feedback coil 252 is uniformly arranged at the left and right of the upper side portion 200, and the Hall device 240 is formed on a lower end portion of the feedback coil 252, that is, a gap of the upper side portion 200.

To minimize a current measurement effect due to the earth magnetism and the measurement depth of the closed loop current sensing circuit in the penetration piece 100, an input/output pattern of the Hall devices 240 passes through a winding center of the feedback coil 252, and the Hall devices 240 are formed on left/right gaps in a parallel structure in a relative direction, that is, a magnetic flux direction. Moreover, a correction variable resistor (not shown) is formed to uniformly set left/right sensitivities of the Hall devices 240, thereby adjusting a supply current of the Hall devices 240.

In order to implement the current flowing into the feedback coil 252 in a single power supply, the closed loop current sensing circuit is formed with a power distribution circuit 253 for distributing supply power to both sides and a current-voltage conversion resistor 254 for converting a current measurement output signal current into a voltage.

Moreover, the current transducer of the present invention includes a signal conversion circuit section having an effective function calculation circuit 255 for a non-sinusoidal wave for converting a measurement signal having the same form as the current of the measurement target line 110 measured from the closed loop current sensing circuit into a DC conversion signal relative to an effective value corresponding to a special signal required by equipment such as a computer, a PLC, recording equipment, display equipment, or the like to provide the DC conversion signal, and a DC signal amplification circuit 256 for amplification to a DC output signal relative to a calculated effective value.

The current transducer of the present invention has the external appearance of the structure in which the penetration piece 100 is open/closed, and can implement current measurement and conversion functions in one product by integrating the closed loop current measurement circuit having the power distribution circuit 253 and the current-voltage conversion resistor 254 and the signal conversion circuit section having the effective function calculation circuit 255 for the non-sinusoidal wave and the DC signal amplification circuit 256. At the time of mounting on the existing installed measurement target line 110, the penetration piece 100 of the current transducer can be easily installed to be open/closed without disassembling the installed line.

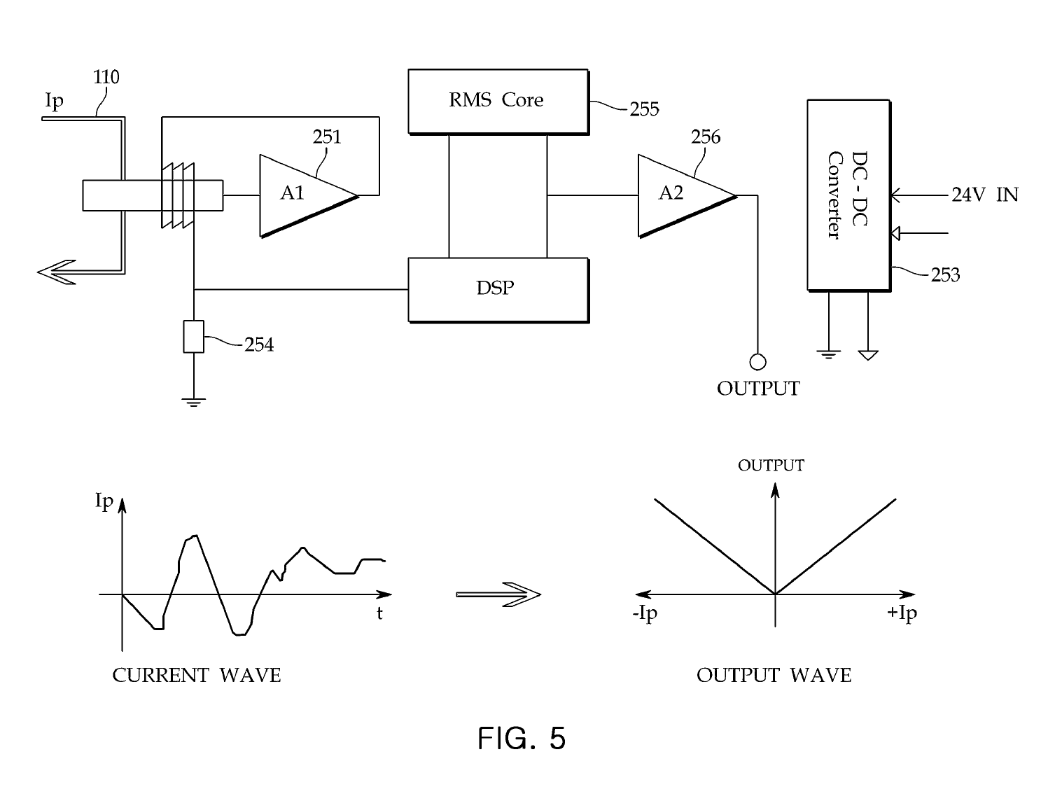

FIG. 5 is a circuit configuration view of the closed loop current transducer having the open/closed structure of the penetration piece according to a preferred embodiment of the present invention.

Referring to FIG. 5, the closed loop current measurement circuit having the power distribution circuit 253 and the current-voltage conversion resistor 254 forms an electromagnetic field proportional to a current amount when the current flows into the measurement target line 110 through the penetration piece 100. The electromagnetic field forms a magnetic field by magnetizing the magnet 350. A magnetic force is formed by a generated magnetic flux density on the gap of the magnet 350, and magnetoelectric conversion is achieved through the Hall devices 250.

A conversion voltage generated through the magnetoelectric conversion of the Hall devices 250 is directly transferred to the voltage-current amplification circuit 251 of the infinite theory, and the voltage-current amplification circuit 251 transfers a current component of an instantaneous amplification output to the feedback coil 252.

The feedback coil 252 is wound in a reverse direction to a current flow of the measurement target line 110, such that the current flows thereinto. At this time, the magnetic flux density of the magnet 350 is instantaneously directed to “0.” When the measurement target line 110 is set to “1,” the current flows into the feedback coil 252 at a ratio of XN turns. The current flowing into the feedback coil 252 forms a current amount at the magnetic flux density of “0.” The closed loop is formed using the current flowing into the feedback coil 252 as a measurement current signal, such that an amount of current flowing into the measurement target line can be measured. This is because the closed loop current sensing circuit is formed by implementing a double power supply on a single power supply when the power distribution circuit 253 forms a virtual power reference point such that a current signal flowing into the feedback coil 252 is incoming/outgoing through the current-voltage conversion resistor 254.

The signal conversion section having the effective function calculation circuit 255 for the non-sinusoidal wave and the current signal amplification circuit 256 is a circuit for converting an output signal measured by the closed loop current sensing circuit into a target output signal, and converts an output signal having the same form as the current of the measurement target line 110 measured by the closed loop current sensing circuit into a DC conversion signal corresponding to a special signal required by equipment such as a computer, a PLC, recording equipment, display equipment, or the like to provide the DC conversion signal. More specifically, the current measurement signal generated in the current-voltage conversion resistor 254 of the closed loop current sensing circuit is output by cross switching a waveform time-divisionally differentiated through the effective function calculation circuit 255 and calculating a DC signal relative to an effective value through a multi-integral method in a DS integral circuit. A signal converted into the DC through the DC signal amplification circuit 256 is amplified to DC 4˜20 mA or DC 1˜5 V corresponding to an output signal form required by the connected equipment and the amplified signal is output.

In order to measure a current without measurement error in the separate type of current transducer of the present invention, it is important to avoid the effect of a gap of the magnet 350 occurring in the separate structure of the upper side portion 200 and the lower side portion 300. This can be realized only in the closed loop of which the magnetic flux density is directed to “0.” This is because a gain is determined by the number of turns of the feedback coil 252 proportional to a current amount to be measured.

When the current transducer of the present invention is used, the current measurement process does not depend upon the characteristics of the magnet 252, such that frequency characteristics can be significantly improved and a frequency bandwidth can be maximally extended according to magnet performance and semiconductor performance of an electronic circuit to be applied. Moreover, a measurement waveform is possible in a range from a DC to an AC of several hundreds kHz. Since the measurement waveform is not limited and a DC conversion circuit relative to a true effective value is provided, a special signal transducer is not required and therefore a unified current transducer having the above-described electrical characteristics can be effectively provided.

While the present invention has been shown and described with reference to certain embodiments, it will be understood by those skilled in the art that various modifications may be made therein without departing from the spirit and scope of the present invention as defined by the appended claims and their equivalents.

1. A current transducer having an open/closed structure of a penetration piece through which a measurement target line passes, comprising:
one pair of Hall devices, formed on both end gaps of an upper side portion, for sensing a current amount of the line to be measured;
a feedback coil, arranged on an upper portion of the Hall devices, for canceling out a magnetic flux density of a magnet by inducing a current of a reverse direction to a current conducted in the measurement target line;
a closed loop current sensing circuit for measuring a current flowing into the feedback coil; and
a signal conversion circuit section for converting a current form of the measurement target line measured from the closed loop current sensing circuit into a direct current conversion signal relative to an effective value required from equipment connected to the current transducer, and outputting the direct current conversion signal.

2. The current transducer having the open/closed structure of the penetration piece according to claim 1, wherein the signal conversion circuit section includes:
an effective function calculation circuit for cross switching a time-divisionally differentiated waveform of a signal measured through the closed loop current measurement circuit, calculating a direct current signal relative to an effective value through a multi-integral method in a DS integral circuit, and outputting the direct current signal; and
a direct current signal amplification circuit for amplifying and outputting the direct current signal output through the effective function calculation circuit.

3. The current transducer having the open/closed structure of the penetration piece according to claim 1, wherein an input/output pattern of the Hall devices is formed to pass through a winding center of the feedback coil, and the Hall devices are formed on left and right gaps in a magnetic flux direction.

4. The current transducer having the open/closed structure of the penetration piece according to claim 1, further comprising:
a correction variable resistor for uniformly adjusting left and right sensitivities of the Hall devices.

5. The current transducer having the open/closed structure of the penetration piece according to claim 1, wherein a length ratio of an upper side portion and a lower side portion of the penetration piece is formed at 8:2 or 9:1.

6. The current transducer having the open/closed structure of the penetration piece according to claim 1, wherein when an upper side portion and a lower side portion are separated with reference to a hinge, the current transducer is rotatable.

7. The current transducer having the open/closed structure of the penetration piece according to claim 6, wherein when the penetration piece of the current transducer configures a closed loop, a fixture for coupling and fixing the upper side portion and the lower side portion is further formed.

8. The current transducer having the open/closed structure of the penetration piece according to claim 1, wherein an attachment hole for accommodating a nut connected to an attachment screw is further formed to attach the current transducer to a frame or bracket.
